(19) United States
(12) Patent Application Publication
(10) Pub. No.: US 2022/0170179 A1
(43) Pub. Date: Jun. 2, 2022

(54) SILICON CARBIDE SUBSTRATE AND METHOD OF MANUFACTURING SILICON CARBIDE SUBSTRATE

(71) Applicant: SUMITOMO ELECTRIC INDUSTRIES, LTD., Osaka (JP)

(72) Inventor: Tsubasa HONKE, Osaka (JP)

(21) Appl. No.: 17/617,126

(22) PCT Filed: May 27, 2020
(86) PCT No.: PCT/JP2020/020904

§ 371 Date: Dec. 7, 2021

(30) Foreign Application Priority Data
Jun. 13, 2019 (JP) 2019-110318

(51) Int. Cl. C30B 29/36; H01L 21/321

(52) U.S. Cl. CPC C30B 29/36; H01L 21/3212

(57) ABSTRACT

A silicon carbide substrate is a silicon carbide substrate including: a first main surface, a shape of the first main surface before the orientation flat is provided being a circle. An average value of LTVs of a plurality of first square regions of a plurality of square regions is less than or equal to 0.75 μm, the plurality of first square regions being disposed in a form of a ring on an outermost side with respect to the center of the circle so as to form an outermost periphery when the central region of the first main surface is divided into the plurality of square regions to provide a largest number of square regions, each of the square regions exactly forming a square having each side of 5 mm.

### TECHNICAL FIELD

The present disclosure relates to a silicon carbide substrate and a method of manufacturing the silicon carbide substrate. The present application claims a priority based on Japanese Patent Application No. 2019-110318 filed on Jun. 13, 2019, the entire content of which is incorporated herein by reference.

### BACKGROUND ART

Japanese Patent Laying-Open No. 2016-139685 (PTL 1) discloses a method of manufacturing a single crystal silicon carbide substrate, the method including a step of performing chemical mechanical polishing onto a mechanically polished main surface of the single crystal silicon carbide substrate.

### CITATION LIST

### Patent Literature

PTL 1: Japanese Patent Laying-Open No. 2016-139685

### SUMMARY OF INVENTION

A silicon carbide substrate according to the present disclosure is a silicon carbide substrate including: a first main surface having a circular shape and provided with an orientation flat; and a second main surface opposite to the first main surface. When a shape of the first main surface before the orientation flat is provided is a circle, the first main surface has a center of the circle. When it is assumed that a first imaginary straight line is provided to extend in a first radial direction of the first main surface through the center of the circle, the first main surface includes first both-end portions in the first radial direction, the first both-end portions being two intersections between the first imaginary straight line and a peripheral edge of the first main surface in the first radial direction. When it is assumed that a second imaginary straight line is provided to extend in a second radial direction of the first main surface through the center of the circle, the first main surface includes second both-end portions in the second radial direction, the second both-end portions being two intersections between the second imaginary straight line and the peripheral edge of the first main surface in the second radial direction, the second radial direction being orthogonal to the first radial direction. The first main surface includes a central region other than a first region and a second region, the first region being a region extending by less than or equal to 5 mm from each of the first both-end portions in the first radial direction toward an inner side of the first main surface, the second region being a region extending by less than or equal to 5 mm from each of the second both-end portions in the second radial direction toward the inner side of the first main surface. An average value of LTVs of a plurality of first square regions of a plurality of square regions is less than or equal to 0.75 μm, the plurality of first square regions being disposed in a form of a ring on an outermost side with respect to the center of the circle so as to form an outermost periphery when the central region of the first main surface is divided into the plurality of square regions to provide a largest number of square regions, each of the square regions exactly forming a square having each side of 5 mm.

A method of manufacturing a silicon carbide substrate according to the present disclosure includes: forming a silicon carbide single crystal wafer by slicing an ingot composed of a silicon carbide single crystal; chamfering the silicon carbide single crystal wafer by cutting a corner of the silicon carbide single crystal wafer; roughly polishing both main surfaces of the chamfered silicon carbide single crystal wafer; performing first both-main-surface chemical mechanical polishing at least once onto the roughly polished silicon carbide single crystal wafer using a polishing cloth and a polishing liquid; and performing second both-main-surface chemical mechanical polishing at least once onto the silicon carbide single crystal wafer having been through the first both-main-surface chemical mechanical polishing, using a polishing cloth and a polishing liquid different from the polishing cloth and the polishing liquid used in the performing of the first both-main-surface chemical mechanical polishing. In at least one of the performing of the first both-main-surface chemical mechanical polishing and the performing of the second both-main-surface chemical mechanical polishing, Aₛᵢ and A_{c} satisfy the following formulas (6) to (8), where Aₛᵢ represents an effective surface area ratio of the polishing cloth for polishing a Si surface of the silicon carbide single crystal wafer, and A_{c} represents an effective surface area ratio of the polishing cloth for polishing a C surface of the silicon carbide single crystal wafer. In at least one of the performing of the first both-main-surface chemical mechanical polishing and the performing of the second both-main-surface chemical mechanical polishing, a ratio (Rₛᵢ/R_{c}) of a polishing rate Rₛᵢ for the Si surface of the silicon carbide single crystal wafer and a polishing rate R_{c} for the C surface of the silicon carbide single crystal wafer is more than or equal to 0.6 and less than or equal to 1.4.

Aₛᵢ≥80 and A_{c}≥80 (6),

Aₛᵢ≥90 and A_{c}<90 (7), and

1<(Aₛᵢ/A_{c})<1.25 (8).

### BRIEF DESCRIPTION OF DRAWINGS

FIG. 1 is a schematic plan view of a silicon carbide substrate according to a first embodiment.

FIG. 2 is a schematic enlarged view of a cross section taken along II-II in FIG. 1.

FIG. 3 is a schematic plan view of a silicon carbide substrate according to a second embodiment.

FIG. 4 is a schematic enlarged view of a cross section taken along IV-IV in FIG. 3.

FIG. 5 is a schematic plan view of a silicon carbide substrate according to a third embodiment.

FIG. 6 is a schematic enlarged view of a cross section taken along VI-VI in FIG. 5.

FIG. 7 is a schematic plan view of a silicon carbide substrate according to a fourth embodiment.

FIG. 8 is a schematic enlarged view of a cross section taken along VIII-VIII in FIG. 7.

FIG. 9 is a flowchart of a method of manufacturing a silicon carbide substrate according to a fifth embodiment.

FIG. 10 is a schematic plan view of an entire surface of an exemplary polishing cloth used in each of a first both-main-surface chemical mechanical polishing step and a second both-main-surface chemical mechanical polishing step.

FIG. 11 is a flowchart of a method of manufacturing a silicon carbide substrate according to a sixth embodiment.

FIG. 12 is a diagram showing results of calculating respective average values of LTVs of first square regions, second square regions, third square regions, fourth square regions, and fifth square region in each of silicon carbide substrates of Experiment Examples 1 to 3.

### DETAILED DESCRIPTION

### Problem to be Solved by the Present Disclosure

An object of the present disclosure is to provide a silicon carbide substrate having a peripheral edge with improved flatness.

### Advantageous Effect of the Present Disclosure

According to the present disclosure, there can be provided a silicon carbide substrate having a peripheral edge with improved flatness.

### DESCRIPTION OF EMBODIMENTS

First, embodiments of the present disclosure are listed and described.

(1) A silicon carbide substrate according to the present disclosure is a silicon carbide substrate including: a first main surface having a circular shape and provided with an orientation flat; and a second main surface opposite to the first main surface, wherein when a shape of the first main surface before the orientation flat is provided is a circle, the first main surface has a center of the circle, when it is assumed that a first imaginary straight line is provided to extend in a first radial direction of the first main surface through the center of the circle, the first main surface includes first both-end portions in the first radial direction, the first both-end portions being two intersections between the first imaginary straight line and a peripheral edge of the first main surface in the first radial direction, when it is assumed that a second imaginary straight line is provided to extend in a second radial direction of the first main surface through the center of the circle, the first main surface includes second both-end portions in the second radial direction, the second both-end portions being two intersections between the second imaginary straight line and the peripheral edge of the first main surface in the second radial direction, the second radial direction being orthogonal to the first radial direction, the first main surface includes a central region other than a first region and a second region, the first region being a region extending by less than or equal to 5 mm from each of the first both-end portions in the first radial direction toward an inner side of the first main surface, the second region being a region extending by less than or equal to 5 mm from each of the second both-end portions in the second radial direction toward the inner side of the first main surface, and an average value of LTVs of a plurality of first square regions of a plurality of square regions is less than or equal to 0.75 μm, the plurality of first square regions being disposed in a form of a ring on an outermost side with respect to the center of the circle so as to form an outermost periphery when the central region of the first main surface is divided into the plurality of square regions to provide a largest number of square regions, each of the square regions exactly forming a square having each side of 5 mm. Since the average value of the LTVs of the plurality of first square regions is less than or equal to 0.75 μm, there can be provided a silicon carbide substrate having a peripheral edge with improved flatness.

(2) In the silicon carbide substrate according to (1), the average value of the LTVs of the plurality of first square regions may be more than or equal to 0.1 μm. Also when the average value of the LTVs of the plurality of first square regions is more than or equal to 0.1 μm, the flatness of the peripheral edge of the silicon carbide substrate can be improved.

(3) An average value of LTVs of a plurality of second square regions of the plurality of square regions may be less than or equal to 0.4 μm, the plurality of second square regions being disposed adjacent to the plurality of first square regions on an inner side in the first radial direction or the second radial direction with respect to the plurality of first square regions, the plurality of second square regions being disposed in a form of a ring so as to form an inner periphery of the ring formed by the plurality of first square regions. Since the average value of the LTVs of the plurality of second square regions is less than or equal to 0.4 μm, the flatness of the peripheral edge of the silicon carbide substrate tends to be improved.

(4) In the silicon carbide substrate according to (3), the average value of the LTVs of the plurality of second square regions may be more than or equal to 0.1 μm. Also when the average value of the LTVs of the plurality of second square regions is more than or equal to 0.1 μm, the flatness of the peripheral edge of the silicon carbide substrate can be improved.

(5) An average value of LTVs of a plurality of third square regions of the plurality of square regions may be less than or equal to 0.3 μm, the plurality of third square regions being disposed adjacent to the plurality of second square regions on an inner side in the first radial direction or the second radial direction with respect to the plurality of second square regions, the plurality of third square regions being disposed in a form of a ring so as to form an inner periphery of the ring formed by the plurality of second square regions. Since the average value of the LTVs of the plurality of third square regions is less than or equal to 0.3 μm, the flatness of the peripheral edge of the silicon carbide substrate tends to be improved.

(6) In the silicon carbide substrate according to (5), the average value of the LTVs of the plurality of third square regions may be more than or equal to 0.1 μm. Also when the average value of the LTVs of the plurality of third square regions is more than or equal to 0.1 μm, the flatness of the peripheral edge of the silicon carbide substrate can be improved.

(7) An average value of LTVs of a plurality of fourth square regions of the plurality of square regions may be less than or equal to 0.25 μm, the plurality of fourth square regions being disposed adjacent to the plurality of third square regions on an inner side in the first radial direction or the second radial direction with respect to the plurality of third square regions, the plurality of fourth square regions being disposed in a form of a ring so as to form an inner periphery of the ring formed by the plurality of third square regions. Since the average value of the LTVs of the plurality of fourth square regions is less than or equal to 0.25 the flatness of the peripheral edge of the silicon carbide substrate tends to be improved.

(8) In the silicon carbide substrate according to (7), the average value of the LTVs of the plurality of fourth square regions may be more than or equal to 0.1 Also when the average value of the LTVs of the plurality of fourth square regions is more than or equal to 0.1 the flatness of the peripheral edge of the silicon carbide substrate can be improved.

(9) A method of manufacturing a silicon carbide substrate according to the present disclosure includes: forming a silicon carbide single crystal wafer by slicing an ingot composed of a silicon carbide single crystal; chamfering the silicon carbide single crystal wafer by cutting a corner of the silicon carbide single crystal wafer; roughly polishing both main surfaces of the chamfered silicon carbide single crystal wafer; performing first both-main-surface chemical mechanical polishing at least once onto the roughly polished silicon carbide single crystal wafer using a polishing cloth and a polishing liquid; and performing second both-main-surface chemical mechanical polishing at least once onto the silicon carbide single crystal wafer having been through the first both-main-surface chemical mechanical polishing, using a polishing cloth and a polishing liquid different from the polishing cloth and the polishing liquid used in the performing of the first both-main-surface chemical mechanical polishing, wherein in at least one of the performing of the first both-main-surface chemical mechanical polishing and the performing of the second both-main-surface chemical mechanical polishing, Aₛᵢ and A_{c} satisfy the following formulas (6) to (8), where Aₛᵢ represents an effective surface area ratio of the polishing cloth for polishing a Si surface of the silicon carbide single crystal wafer, and A_{c} represents an effective surface area ratio of the polishing cloth for polishing a C surface of the silicon carbide single crystal wafer, and in at least one of the performing of the first both-main-surface chemical mechanical polishing and the performing of the second both-main-surface chemical mechanical polishing, a ratio (Rₛᵢ/R_{c}) of a polishing rate Rₛᵢ for the Si surface of the silicon carbide single crystal wafer and a polishing rate R_{c} for the C surface of the silicon carbide single crystal wafer is more than or equal to 0.6 and less than or equal to 1.4. By the method of manufacturing the silicon carbide substrate according to the present disclosure, there can be manufactured a silicon carbide substrate having a peripheral edge with improved flatness.

Aₛᵢ≥80 and A_{c}≥80 (6),

Aₛᵢ≥90 and A_{c}<90 (7), and

1<(Aₛᵢ/A_{c})<1.25 (8).

### DETAILS OF EMBODIMENTS OF THE PRESENT DISCLOSURE

Hereinafter, embodiments of the present disclosure will be described in detail. In the following description, the same or corresponding elements are denoted by the same reference characters, and will not be described repeatedly.

### First Embodiment

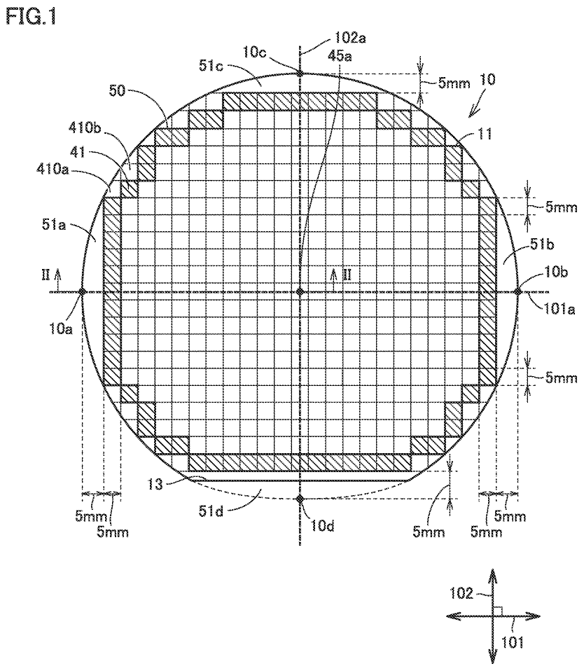

FIG. 1 is a schematic plan view of a silicon carbide substrate 10 according to a first embodiment. As shown in the schematic plan view of FIG. 1, silicon carbide substrate 10 according to the first embodiment includes a first main surface 11. First main surface 11 is provided with an orientation flat 13.

First main surface 11 includes both end portions 10a, 10b in a first radial direction 101. Both end portions 10a, 10b of first main surface 11 in first radial direction 101 refer to two intersections between a first imaginary straight line 101a and the peripheral edge of first main surface 11 when it is assumed that first imaginary straight line 101a is provided at first main surface 11 to extend in first radial direction 101.

First imaginary straight line 101a is an imaginary straight line extending in first radial direction 101 through center 45a of first main surface 11. Center 45a of first main surface 11 refers to the center thereof when the shape of first main surface 11 is a circle (for example, a circle before orientation flat 13 is provided). First radial direction 101 can be set to be any direction of first main surface 11, for example.

First main surface 11 includes both end portions 10c, 10d in a second radial direction 102. Both end portions 10c, 10d of first main surface 11 in second radial direction 102 refer to two intersections between a second imaginary straight line 102a and the peripheral edge of first main surface 11 when it is assumed that second imaginary straight line 102a is provided at first main surface 11 to extend in second radial direction 102.

Second imaginary straight line 102a is an imaginary straight line extending in second radial direction 101 through center 45a of first main surface 11. Second radial direction 102 is a direction orthogonal to first radial direction 101.

First main surface 11 includes first regions 51a, 51b extending by less than or equal to 5 mm from respective both end portions 10a, 10b of first main surface 11 in first radial direction 101 toward the inner side of first main surface 11. First main surface 11 includes second regions 51c, 51d extending by less than or equal to 5 mm from respective both end portions 10c, 10d of first main surface 11 in second radial direction 102 toward the inner side of first main surface 11. First main surface 11 includes a central region 50, which is a region obtained by excluding first regions 51a, 51b and second regions 51c, 51d from the entire region of first main surface 11.

As shown in FIG. 1, for example, central region 50 is divided into a plurality of square regions each having each side of 5 mm. Central region 50 is divided into the plurality of square regions to provide the largest number of square regions each having each side of 5 mm. As each square region, only a region that exactly forms a square is recognized. A region that does not exactly form a square due to lacking of a portion thereof or the like is not recognized as the square region.

First square regions 41 of the plurality of divided square regions of central region 50 are square regions that form an outermost periphery. First square regions 41 refer to square regions that are included in the plurality of divided square regions of central region 50, that each completely form a square, and that are located on the outermost side of central region 50.

For example, in the example shown in FIG. 1, a region 410a is located on the outer side of central region 50 (the peripheral edge side of first main surface 11) with respect to a first square region 41 in first radial direction 101. A region 410b is located on the outer side of central region 50 with respect to first square region 41 in second radial direction 102. However, as shown in FIG. 1, since each of regions 410a, 410b does not exactly form a square, regions 410a, 410b are not recognized as the square regions.

Therefore, first square regions 41 are recognized as first square regions 41 that form the outermost periphery. Central region 50 includes the plurality of first square regions 41. The plurality of first square regions 41 are disposed in the form of a ring to form the outermost periphery of the plurality of square regions of central region 50 as shown in FIG. 1, for example.

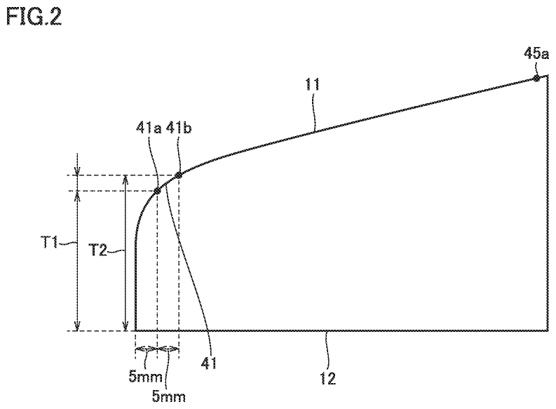

FIG. 2 is a schematic enlarged view of a cross section taken along II-II in FIG. 1. FIG. 2 shows an LTV (Local Thickness Variation) of each first square region 41. The LTV of first square region 41 is a value obtained by subtracting, from a height T2 from second main surface 12 to a highest point 41b of first main surface 11, a height T1 from second main surface 12 to a lowest point 41a of first main surface 11 in first square region 41 in such a state that second main surface 12 opposite to first main surface 11 is entirely adsorbed to a flat adsorption surface.

That is, the LTV of first square region 41 is calculated by the following formula (1):

The LTV of first square region 41=|T2−T1| (1).

The LTV is an index that quantitatively indicates flatness of first main surface 11 of silicon carbide substrate 10. The LTV can be measured by using, for example, “Tropel FlatMaster (registered trademark)” manufactured by Corning Tropel.

The LTV is measured for each of the plurality of first square regions 41 that form the outermost periphery of the plurality of square regions of central region 50. Then, the average value of LTVs is calculated from the measured values of the LTVs of the plurality of first square regions 41. The average value of the LTVs is regarded as the average value of the LTVs of the plurality of first square regions 41 of silicon carbide substrate 10 according to the first embodiment.

The average value of the LTVs of the plurality of first square regions 41 of silicon carbide substrate 10 according to the first embodiment is less than or equal to 0.75 μm. This means that the flatness of the peripheral edge of silicon carbide substrate 10 according to the first embodiment is improved as compared with the conventional silicon carbide substrate. Thus, in silicon carbide substrate 10 according to the first embodiment, a device fabrication region can be increased up to a region closer to the peripheral edge of first main surface 11 of silicon carbide substrate 10 as compared with the conventional silicon carbide substrate, with the result that a larger number of devices can be fabricated from one silicon carbide substrate 10.

### Second Embodiment

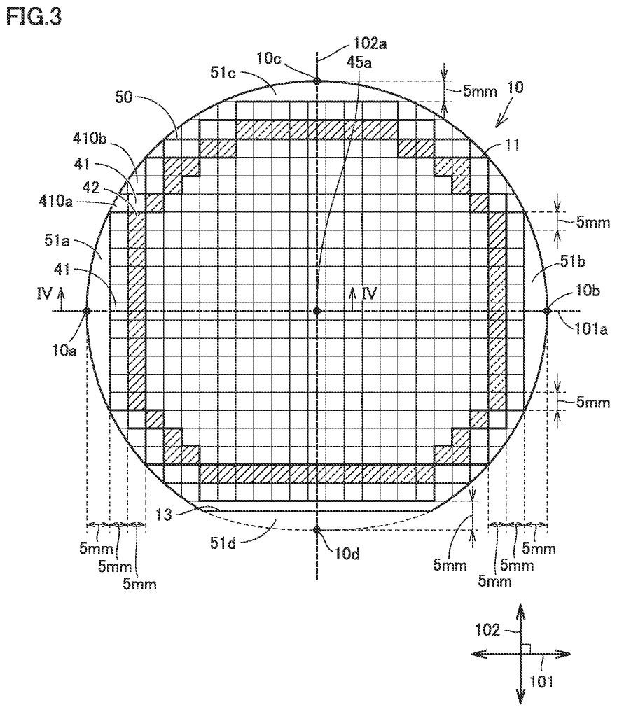

FIG. 3 is a schematic plan view of a silicon carbide substrate 10 according to a second embodiment. A feature of silicon carbide substrate 10 according to the second embodiment lies in that the average value of LTVs of second square regions 42 is less than or equal to 0.4 μm.

Second square regions 42 are square regions that are included in the plurality of divided square regions of central region 50, that are disposed on the inner side in first radial direction 101 or second radial direction 102 with respect to first square regions 41, and that are located adjacent to first square regions 41.

The plurality of divided square regions of central region 50 include the plurality of second square regions 42. Second square regions 42 are disposed in the form of a ring so as to form an inner periphery of the ring formed by first square regions 41 as shown in FIG. 3, for example.

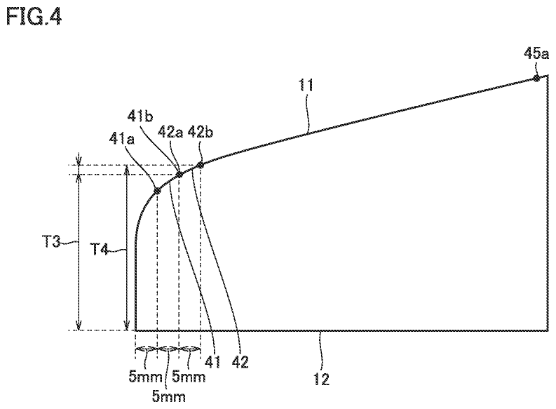

FIG. 4 is a schematic enlarged view of a cross section taken along IV-IV in FIG. 3. FIG. 4 shows an LTV of each second square region 42. The LTV of second square region 42 is a value obtained by subtracting, from a height T4 from second main surface 12 to a highest point 42b of first main surface 11, a height T3 from second main surface 12 to a lowest point 42a of first main surface 11 in second square region 42 in such a state that second main surface 12 opposite to first main surface 11 is entirely adsorbed to a flat adsorption surface.

That is, the LTV of second square region 42 is calculated by the following formula (2):

The LTV of second square region 42=|T4−T3| (2).

The LTV is measured for each of the plurality of second square regions 42 disposed in the form of the ring so as to form the inner periphery of the ring of first square regions 41. Then, the average value of LTVs is calculated from the measured values of the LTVs of the plurality of second square regions 42. The average value of the LTVs is regarded as the average value of the LTVs of the plurality of second square regions 42 of silicon carbide substrate 10 according to the second embodiment.

The average value of the LTVs of the plurality of second square regions 42 of silicon carbide substrate 10 according to the second embodiment is less than or equal to 0.4 μm. When the average value of the LTVs of second square regions 42 is less than or equal to 0.4 μm, the average value of the LTVs of first square regions 41 adjacent to second square regions 42 on the outer side tends to also have a low value. This means that improved flatness of the peripheral edge of silicon carbide substrate 10 according to the second embodiment is resulted.

Therefore, also in silicon carbide substrate 10 according to the second embodiment, a device fabrication region can be increased up to a region closer to the peripheral edge of first main surface 11 of silicon carbide substrate 10 as compared with the conventional silicon carbide substrate, with the result that a larger number of devices can be fabricated from one silicon carbide substrate 10.

The explanation of the second embodiment other than the above is the same as that of the first embodiment, and therefore will not be described.

### Third Embodiment

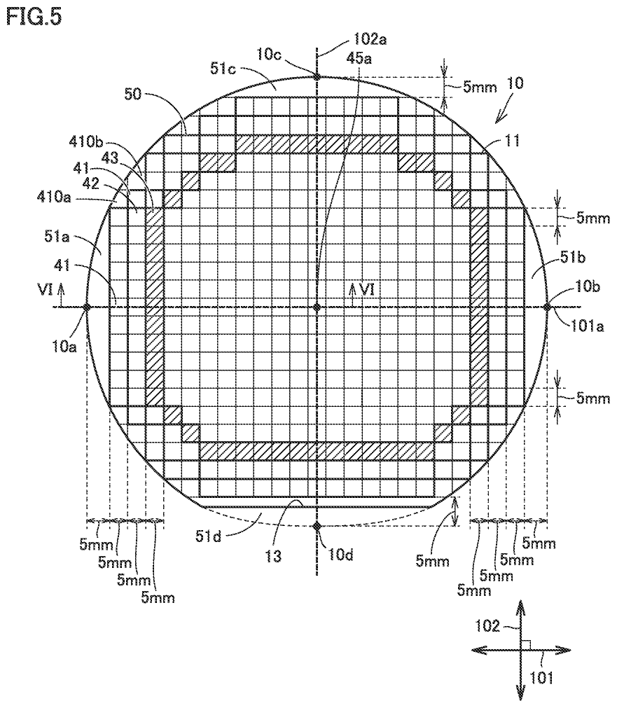

FIG. 5 is a schematic plan view of a silicon carbide substrate 10 according to a third embodiment. A feature of silicon carbide substrate 10 according to the third embodiment lies in that the average value of LTVs of third square regions 43 is less than or equal to 0.3 μm.

Third square regions 43 are square regions that are included in the plurality of divided square regions of central region 50, that are disposed on the inner side in first radial direction 101 or second radial direction 102 with respect to second square regions 42, and that are located adjacent to second square regions 42.

The plurality of divided square regions of central region 50 include the plurality of third square regions 43. Third square regions 43 are disposed in the form of a ring so as to form an inner periphery of the ring formed by second square regions 42 as shown in FIG. 5, for example.

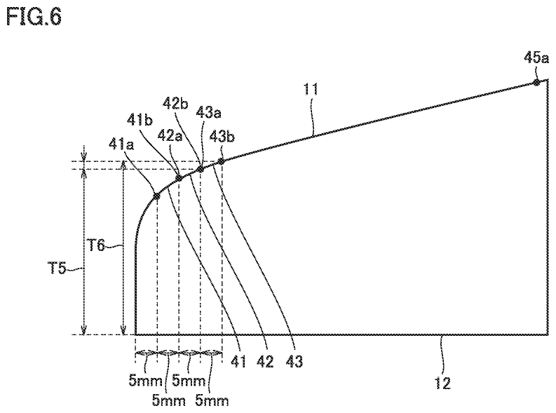

FIG. 6 is a schematic enlarged view of a cross section taken along VI-VI in FIG. 5. FIG. 6 shows an LTV of each third square region 43. The LTV of third square region 43 is a value obtained by subtracting, from a height T6 from second main surface 12 to a highest point 43b of first main surface 11, a height T5 from second main surface 12 to a lowest point 43a of first main surface 11 in third square region 43 in such a state that second main surface 12 opposite to first main surface 11 is entirely adsorbed to a flat adsorption surface.

That is, the LTV of third square region 43 is calculated by the following formula (3):

The LTV of third square region 43=|T6−T5| (3).

The LTV is measured for each of the plurality of third square regions 43 disposed in the form of the ring so as to form the inner periphery of the ring of second square regions 42. Then, the average value of LTVs is calculated from the measured values of the LTVs of the plurality of third square regions 43. The average value of the LTVs is regarded as the average value of the LTVs of the plurality of third square regions 43 of silicon carbide substrate 10 according to the third embodiment.

The average value of the LTVs of the plurality of third square regions 43 of silicon carbide substrate 10 according to the third embodiment is less than or equal to 0.3 μm. When the average value of the LTVs of third square regions 43 is less than or equal to 0.3 μm, the average value of the LTVs of second square regions 42 adjacent to third square regions 43 on the outer side and the average value of the LTVs of first square regions 41 adjacent to second square regions 42 on the outer side tend to also have low values. This means that improved flatness of the peripheral edge of silicon carbide substrate 10 according to the third embodiment is resulted.

Therefore, also in silicon carbide substrate 10 according to the third embodiment, a device fabrication region can be increased up to a region closer to the peripheral edge of first main surface 11 of silicon carbide substrate 10 as compared with the conventional silicon carbide substrate, with the result that a larger number of devices can be fabricated from one silicon carbide substrate 10.

The explanation of the third embodiment other than the above is the same as those of the first and second embodiments, and therefore will not be described.

### Fourth Embodiment

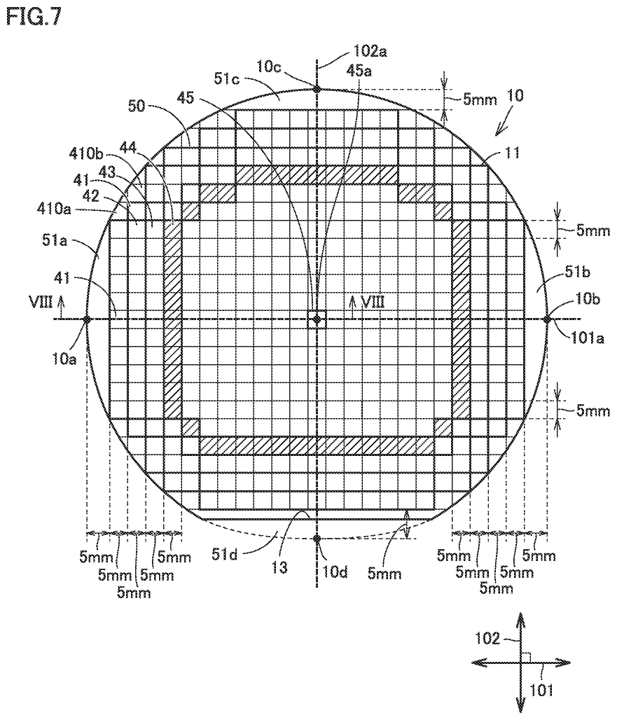

FIG. 7 is a schematic plan view of a silicon carbide substrate 10 according to a fourth embodiment. A feature of silicon carbide substrate 10 according to the fourth embodiment lies in that the average value of LTVs of fourth square regions 44 is less than or equal to 0.25 μm.

Fourth square regions 44 are square regions that are included in the plurality of divided square regions of central region 50, that are disposed on the inner side in first radial direction 101 or second radial direction 102 with respect to third square regions 43, and that are located adjacent to third square regions 43.

The plurality of divided square regions of central region 50 include the plurality of fourth square regions 44. Fourth square regions 44 are disposed in the form of a ring so as to form an inner periphery of the ring formed by third square regions 43 as shown in FIG. 7, for example.

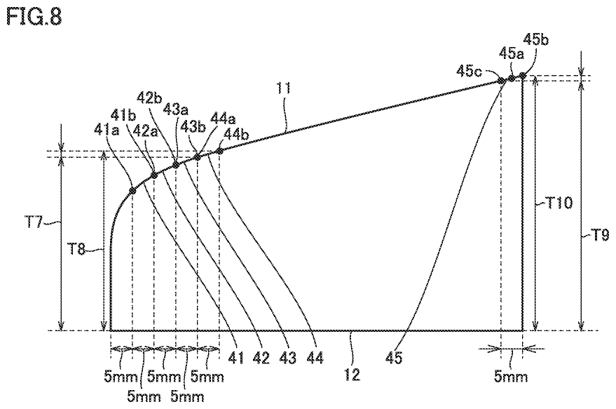

FIG. 8 is a schematic enlarged view of a cross section taken along VIII-VIII in FIG. 7. FIG. 8 shows an LTV of each fourth square region 44. The LTV of fourth square region 44 is a value obtained by subtracting, from a height T8 from second main surface 12 to a highest point 44b of first main surface 11, a height T7 from second main surface 12 to a lowest point 44a of first main surface 11 in fourth square region 44 in such a state that second main surface 12 opposite to first main surface 11 is entirely adsorbed to a flat adsorption surface.

That is, the LTV of fourth square region 44 is calculated by the following formula (4):

The LTV of fourth square region 44=|T8−T7| (4).

The LTV is measured for each of the plurality of fourth square regions 44 disposed in the form of the ring so as to form the inner periphery of the ring of third square regions 43. Then, the average value of LTVs is calculated from the measured values of the LTVs of the plurality of fourth square regions 44. The average value of the LTVs is regarded as the average value of the LTVs of the plurality of fourth square regions 44 of silicon carbide substrate 10 according to the fourth embodiment.

The average value of the LTVs of the plurality of fourth square regions 44 of silicon carbide substrate 10 according to the fourth embodiment is less than or equal to 0.25 μm. When each of fourth square regions 44 has high flatness, the average value of the LTVs of third square regions 43 adjacent to fourth square regions 44 on the outer side, the average value of the LTVs of second square regions 42 adjacent to third square regions 43 on the outer side, and the average value of the LTVs of first square regions 41 adjacent to second square regions 42 on the outer side tend to also have low values. This means that improved flatness of the peripheral edge of silicon carbide substrate 10 according to the third embodiment is resulted.

Thus, also in silicon carbide substrate 10 according to the fourth embodiment, a device fabrication region can be increased up to a region closer to the peripheral edge of first main surface 11 of silicon carbide substrate 10 as compared with the conventional silicon carbide substrate, with the result that a larger number of devices can be fabricated from one silicon carbide substrate 10.

Further, FIG. 8 shows an LTV of a fifth square region 45 at center 45a of first main surface 11. The LTV of fifth square region 45 is a value obtained by subtracting, from a height T10 from second main surface 12 to a highest point 45b of first main surface 11, a height T9 from second main surface 12 to a lowest point 45c of first main surface 11 in fifth square region 45 in such a state that second main surface 12 opposite to first main surface 11 is entirely adsorbed to a flat adsorption surface. For example, as shown in FIG. 7, fifth square region 45 is constituted of a square having each side of 5 mm. The intersection of diagonal lines of the square that forms fifth square region 45 is center 45a.

That is, the LTV of fifth square region 45 is calculated by the following formula (5):

The LTV of fifth square region 45=|T10−T9| (5).

The explanation of the fourth embodiment other than the above is the same as those of the first to third embodiments, and therefore will not be described.

Further, in each of the first to fourth embodiments, the average value of LTVs of at least one type of regions selected from a group consisting of first square regions 41, second square regions 42, third square regions 43, and fourth square regions 44 can be more than or equal to 0.1 μm. Also in this case, the flatness of the peripheral edge of silicon carbide substrate 10 according to each of the first to fourth embodiments tends to be improved.

### Fifth Embodiment

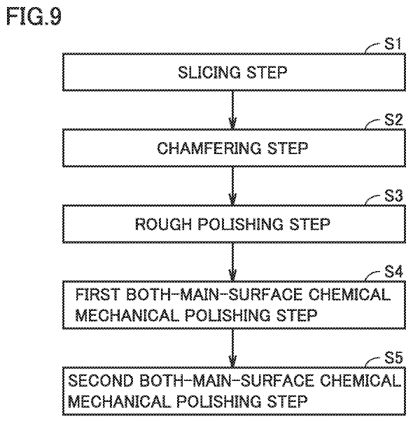

FIG. 9 is a flowchart of a method of manufacturing a silicon carbide substrate according to a fifth embodiment.

As shown in FIG. 9, in the method of manufacturing the silicon carbide substrate according to the fifth embodiment, a slicing step Si is performed first. Slicing step Si can be performed by slicing, using a wire saw, an ingot composed of a silicon carbide single crystal produced by a sublimation method, for example.

Next, a chamfering step S2 is performed. Chamfering step S2 can be performed by cutting a corner of the silicon carbide single crystal wafer obtained through slicing step S1, for example.

Next, a rough polishing step S3 is performed. Rough polishing step S3 can be performed by mechanically polishing both main surfaces of the silicon carbide single crystal wafer having been through chamfering step S2, for example. Examples of the mechanical polishing include grinding or lapping.

Next, a first both-main-surface chemical mechanical polishing step S4 is performed. First both-main-surface chemical mechanical polishing step S4 can be performed by performing chemical mechanical polishing (CMP) onto the both main surfaces of the silicon carbide single crystal wafer having been through rough polishing step S3, under conditions shown in Table 1 below.

First both-main-surface chemical mechanical polishing step S4 is performed as follows. First, a polishing cloth shown in Table 1 is placed on each of respective surfaces of upper and lower surface plates. Next, the silicon carbide single crystal wafer is sandwiched between the polishing cloth on the upper surface plate and the polishing cloth on the lower surface plate, and a surface pressure shown in Table 1 is applied to the silicon carbide single crystal wafer. Next, the upper surface plate and the lower surface plate are rotated in opposite directions at a surface plate rotation speed shown in Table 1 while supplying a polishing liquid shown in Table 1 to the upper and lower main surfaces of the silicon carbide single crystal wafer. On this occasion, the silicon carbide single crystal wafer between the upper surface plate and the lower surface plate is also rotated via a carrier in the same direction as the rotation direction of one of the upper surface plate or the lower surface plate.

It should be noted that the description “Upper:Lower=3:2” in the section “Relative Speed Ratio” in Table 1 means that a ratio of a relative rotation speed of the upper surface plate for polishing the silicon surface (Si surface) that is the upper main surface of the silicon carbide single crystal wafer with respect to the rotation speed of the silicon carbide single crystal wafer and a relative rotation speed of the lower surface plate for polishing the carbon surface (C surface) that is the lower main surface of the silicon carbide single crystal wafer with respect to the rotation speed of the silicon carbide single crystal wafer (the relative rotation speed of the upper surface plate:the rotation speed of the lower surface plate) is 3:2. For example, it is assumed that the upper surface plate is rotated clockwise at a rotation speed of 30 rpm, the silicon carbide single crystal wafer is rotated counterclockwise at a rotation speed of 6 rpm, and the lower surface plate is rotated counterclockwise at a rotation speed of 30 rpm. In this case, the relative rotation speed of the upper surface plate with respect to the rotation speed of the silicon carbide single crystal wafer is 36 rpm (30 rpm+6 rpm=36 rpm), and the relative rotation speed of the lower surface plate with respect to the rotation speed of the silicon carbide single crystal wafer is 24 rpm (30 rpm−6 rpm=24 rpm). Therefore, the description in the section “Relative Speed Ratio” in Table 1 in this case is “Upper:Lower=3:2 (=36 rpm:24 rpm)”.

TABLE 1

| Polishing Liquid | DSC-201 | |
|---|---|---|
| | (Fujimi Incorporated) | |
| Polishing Cloth | SUBA800 | |
| (Nonwoven | (Nitta Haas) | |
| Fabric) | | |
| Surface Plate | 30 | rpm |
| Rotation Speed | | |
| Relative Speed | Upper:Lower = 3:2 | |
| Ratio | | |
| Surface Pressure | 300 | g/cm² |

Next, a second both-main-surface chemical mechanical polishing step S5 is performed. Second both-main-surface chemical mechanical polishing step S5 can be performed by performing chemical mechanical polishing onto the both main surfaces of the silicon carbide single crystal wafer having been through first both-main-surface chemical mechanical polishing step S4, under conditions shown in Table 2 below. It should be noted that second both-main-surface chemical mechanical polishing step S5 is performed in the same manner as first both-main-surface chemical mechanical polishing step S4, except that the polishing liquid and the polishing cloth are changed to those in the conditions shown in Table 2.

TABLE 2

| Polishing Liquid | DSC-0902 | |
|---|---|---|
| | (Fujimi Incorporated) | |
| Polishing Cloth | supreme | |
| (Suede) | (Nitta Haas) | |
| Surface Plate | 30 | rpm |
| Rotation Speed | | |
| Relative Speed | Upper:Lower = 3:2 | |
| Ratio | | |
| Surface Pressure | 300 | g/cm² |

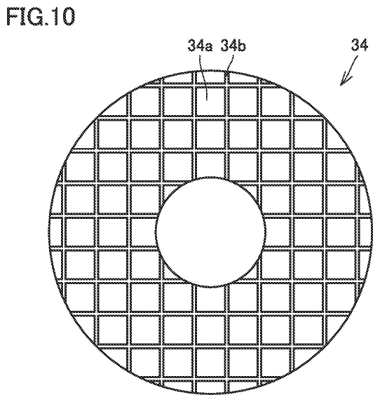

FIG. 10 is a schematic plan view of the entire surface of an exemplary polishing cloth 34 used in each of first both-main-surface chemical mechanical polishing step S4 and second both-main-surface chemical mechanical polishing step S5.

As shown in FIG. 10, the entire doughnut-shaped surface of polishing cloth 34 has such a configuration that an effective polishing surface 34a that contributes to the polishing of the main surface of the silicon carbide single crystal wafer by polishing cloth 34 is provided with a lattice-shaped groove 34b that does not contribute to the polishing of the main surface of the silicon carbide single crystal wafer by polishing cloth 34.

In order to suppress the silicon carbide single crystal wafer from being cracked, broken or chipped due to the both-main-surface CMP, in at least one of first both-main-surface chemical mechanical polishing step S4 and second both-main-surface chemical mechanical polishing step S5, Aₛᵢ and A_{c} preferably satisfy the following formulas (6) to (8) and more preferably satisfy the following formulas (6) to (9), where Aₛᵢ represents an effective surface area ratio of polishing cloth 34 for polishing the Si surface of the both main surfaces of the silicon carbide single crystal wafer, and A_{c} represents an effective surface area ratio of polishing cloth 34 for polishing the C surface of the both main surfaces of the silicon carbide single crystal wafer.

Aₛᵢ≥80 and A_{c}≥80 (6),

Aₛᵢ≥90 and A_{c}<90 (7),

1<(Aₛᵢ/A_{c})<1.25 (8), and

1.02<(Aₛᵢ/A_{c})<1.05 (9).

Effective surface area ratio Aₛᵢ [%] of polishing cloth 34 for polishing the Si surface of the silicon carbide single crystal wafer can be calculated by the following formula (10):

Effective surface area ratio Aₛᵢ [%]=100×{(the area [mm²] of effective polishing surface 34a of polishing cloth 34 for polishing the Si surface of the silicon carbide single crystal wafer)/(the area [mm²] of the entire surface of polishing cloth 34)} (10).

Effective surface area ratio A_{c} [%] of polishing cloth 34 for polishing the C surface of the silicon carbide single crystal wafer can be calculated by the following formula (11):

Effective surface area ratio A_{c} [%]=100×{(the area [mm²] of effective polishing surface 34a of polishing cloth 34 for polishing the C surface of the silicon carbide single crystal wafer)/(the area [mm²] of the entire surface of polishing cloth 34)} (11).

It should be noted that the area [mm²] of the entire surface of polishing cloth 34 in each of the above formulas (10) and (11) refers to the entire area of the surface of polishing cloth 34 when the surface of polishing cloth 34 is viewed in a plan view as shown in FIG. 10, for example.

Further, in order to suppress the silicon carbide single crystal wafer from being cracked, broken or chipped due to the both-main-surface CMP, in at least one of first both-main-surface chemical mechanical polishing step S4 and second both-main-surface chemical mechanical polishing step S5, a ratio (Rₛᵢ/R_{c}) of a polishing rate Rₛᵢ for the Si surface of the silicon carbide single crystal wafer and a polishing rate R_{c} for the C surface of the silicon carbide single crystal wafer is preferably more than or equal to 0.6 and less than or equal to 1.4, is more preferably more than or equal to 0.7 and less than or equal to 1.3, and is further preferably more than or equal to 0.8 and less than or equal to 1.2. It should be noted that the polishing rate refers to an amount by which the silicon carbide single crystal wafer is polished per unit time. The polishing rate can be adjusted by adjusting a polishing condition, for example.

### Sixth Embodiment

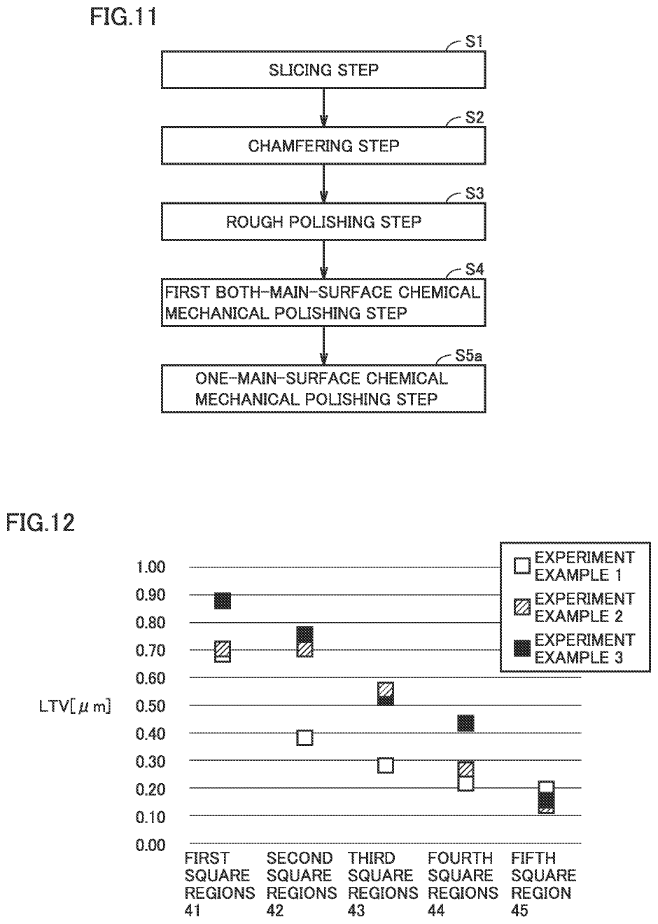

FIG. 11 is a flowchart of a method of manufacturing a silicon carbide substrate according to a sixth embodiment.

As shown in FIG. 11, also in the method of manufacturing the silicon carbide substrate according to the sixth embodiment, slicing step S1, chamfering step S2, rough polishing step S3, and first both-main-surface chemical mechanical polishing step S4 are performed in this order. The explanations of these steps are the same as those described in the fifth embodiment, and therefore will not be described.

Next, a one-main-surface chemical mechanical polishing step S5a is performed. One-main-surface chemical mechanical polishing step S5a can be performed by performing chemical mechanical polishing onto the Si surface and the C surface of the silicon carbide single crystal wafer having been through first both-main-surface chemical mechanical polishing step S4, one after the other under conditions shown in Table 3 below.

One-main-surface chemical mechanical polishing step S5a is performed as follows. First, a polishing cloth shown in Table 3 is placed on a surface of a surface plate. Next, the silicon carbide single crystal wafer is held by a polishing head such that a main surface of the silicon carbide single crystal wafer faces the polishing cloth. Next, a polishing liquid shown in Table 3 is supplied between the polishing cloth and the main surface of the silicon carbide single crystal wafer. Next, a surface pressure shown in Table 3 is applied to the silicon carbide single crystal wafer. Here, the main surface of the silicon carbide single crystal wafer to be polished is brought into contact with the polishing cloth. Next, the surface plate and the polishing head are rotated in the same direction at a surface plate rotation speed shown in Table 3. This operation is performed onto the main surfaces of the silicon carbide single crystal wafer one after the other.

TABLE 3

| Polishing Liquid | DSC-0902 | |
|---|---|---|
| | (Fujimi Incorporated) | |
| Polishing Cloth | supreme | |
| (Suede) | (Nitta Haas) | |
| Surface Plate | 60 | rpm |
| Rotation Speed | | |
| Head Rotation | 100 | rpm |
| Speed | | |
| Surface Pressure | 500 | g/cm² |

### EXAMPLES

### Experiment Example 1

In an Experiment Example 1, a silicon carbide substrate was manufactured in accordance with the flowchart of the method of manufacturing the silicon carbide substrate shown in FIG. 9. Specifically, the silicon carbide substrate was manufactured as follows.

First, slicing step S1 was performed by slicing, using a wire saw, an ingot composed of a silicon carbide single crystal produced by a sublimation method.

Next, chamfering step S2 was performed by cutting a corner of the silicon carbide single crystal wafer obtained through slicing step S1.

Next, rough polishing step S3 was performed by mechanically polishing both main surfaces of the silicon carbide single crystal wafer having been through chamfering step S2.

Next, first both-main-surface chemical mechanical polishing step S4 was performed by performing chemical mechanical polishing onto the both main surfaces of the silicon carbide single crystal wafer having been through rough polishing step S3 as described above, under the conditions shown in Table 1 above.

Next, second both-main-surface chemical mechanical polishing step S5 was performed by performing chemical mechanical polishing onto the both main surfaces of the silicon carbide single crystal wafer having been through first both-main-surface chemical mechanical polishing step S4 as described above, under the conditions shown in Table 2 above. In this way, the silicon carbide substrate of Experiment Example 1 was manufactured.

### Experiment Example 2

In an Experiment Example 2, a silicon carbide substrate was manufactured in accordance with the flowchart of the method of manufacturing the silicon carbide substrate shown in FIG. 11. That is, in Experiment Example 2, the silicon carbide substrate of Experiment Example 2 was manufactured in the same manner as in Experiment Example 1 except that one-main-surface chemical mechanical polishing step S5a was performed instead of second both-main-surface chemical mechanical polishing step S5 of Experiment Example 1.

Specifically, one-main-surface chemical mechanical polishing step S5a was performed by performing chemical mechanical polishing onto the Si surface and the C surface of the silicon carbide single crystal wafer having been through the first both-main-surface chemical mechanical polishing step S4 one after the other as described above under the conditions shown in Table 3 above.

### Experiment Example 3

In an Experiment Example 3, a silicon carbide substrate of Experiment Example 3 was manufactured in the same manner as in Experiment Example 2 except that instead of first both-main-surface chemical mechanical polishing step S4, a one-main-surface chemical mechanical polishing step was performed by performing chemical mechanical polishing onto the Si surface and the C surface of the silicon carbide single crystal wafer having been through rough polishing step S3 one after the other under conditions shown in Table 4.

TABLE 4

| Polishing Liquid | DSC-201 | |
|---|---|---|
| | (Fujimi Incorporated) | |
| Polishing Cloth | SUBA800 | |
| (Nonwoven | (Nitta Haas) | |
| Fabric) | | |
| Surface Plate | 60 | rpm |
| Rotation Speed | | |
| Head Rotation | 100 | rpm |
| Speed | | |
| Surface Pressure | 500 | g/cm² |

<Evaluations>

For each of the silicon carbide substrates of Experiment Examples 1 to 3, the average value of the LTVs of first square regions 41, the average value of the LTVs of second square regions 42, the average value of the LTVs of third square regions 43, and the average value of the LTVs of fourth square regions 44 were calculated. The LTV of one fifth square region 45 was calculated. Results are shown in Table 5 below. FIG. 12 shows a diagram in which the values of the LTVs shown in Table 5 are plotted for the respective Experiment Examples. In FIG. 12, it is indicated that as the value of an LTV is plotted at a lower position, a corresponding region is flatter. Further, in FIG. 12, it is indicated that a direction from fifth square region 45 toward first square regions 41 corresponds to a direction from the center of the silicon carbide substrate toward the peripheral edge of the silicon carbide substrate.

TABLE 5

| | Experiment | Experiment | Experiment |
|---|---|---|---|
| | Example 1 | Example 2 | Example 3 |
| Average Value of LTVs of First | 0.69 | 0.71 | 0.88 |
| Square Regions 41 | | | |
| Average Value of LTVs of | 0.38 | 0.71 | 0.76 |
| Second Square Regions 42 | | | |
| Average Value of LTVs of | 0.28 | 0.56 | 0.53 |
| Third Square Regions 43 | | | |
| Average Value of LTVs of | 0.22 | 0.27 | 0.43 |
| Fourth Square Regions 44 | | | |
| LTV of Fifth Square Region 45 | 0.20 | 0.14 | 0.15 |

As shown in FIG. 12, it is understood that each of the silicon carbide substrates of Experiment Examples 1 and 2 is flatter than the silicon carbide substrate of Experiment Example 3 in the direction from the center of the silicon carbide substrate toward the periphery of the silicon carbide substrate.

Further, as shown in FIG. 12, it is understood that the silicon carbide substrate of Experiment Example 1 is flatter than the silicon carbide substrate of Experiment Example 2 in the direction from the center of the silicon carbide substrate toward the periphery of the silicon carbide substrate.

### Experiment Example 4

In Experiment Example 1, the ratio (Rₛᵢ/R_{c}) of the polishing rate (Rₛᵢ) for the Si surface of the silicon carbide single crystal wafer and the polishing rate (R_{c}) for the C surface of the silicon carbide single crystal wafer was changed to evaluate a non-defective product ratio [%] of silicon carbide single crystal wafers having been through first both-main-surface chemical mechanical polishing step S4. Results are shown in Table 6.

TABLE 6

| | Non-Defective |
|---|---|
| | Product Ratio |
| Rₛᵢ/R_{c} | [%] |
| Less Than or Equal To 0.5 and | 62 |
| More Than 1.8 | |
| More Than or Equal To 0.6 and | 84 |
| Less Than or Equal To 1.4 | |
| More Than or Equal To 0.7 and | 91 |
| Less Than or Equal To 1.3 | |
| More Than or Equal To 0.8 and | 94 |
| Less Than or Equal To 1.2 | |

Based on the results shown in Table 6, it is understood that in order to improve the non-defective product ratio [%] of the silicon carbide single crystal wafers, the ratio (Rₛᵢ/R_{c}) of the polishing rate (Rₛᵢ) for the Si surface of the silicon carbide single crystal wafer and the polishing rate (R_{c}) for the C surface of the silicon carbide single crystal wafer in first both-main-surface chemical mechanical polishing step S4 in Experiment Example 1 is preferably more than or equal to 0.6 and less than or equal to 1.4, is more preferably more than or equal to 0.7 and less than or equal to 1.3, and is further preferably more than or equal to 0.8 and less than or equal to 1.2.

### Experiment Example 5

In Experiment Example 1, the ratio (Rₛᵢ/R_{c}) of the polishing rate (Rₛᵢ) for the Si surface of the silicon carbide single crystal wafer and the polishing rate (R_{c}) for the C surface of the silicon carbide single crystal wafer was changed to evaluate, in accordance with below-described criteria, states of silicon carbide single crystal wafers having been through first both-main-surface chemical mechanical polishing step S4. Results are shown in Table 7.

(Criteria)

A . . . smallest LTV

B . . . small LTV

C . . . LTV less than or equal to a criterion

D . . . deteriorated LTV

E . . . insufficient

TABLE 7

| | | Rₛᵢ | | | | | | |
|---|---|---|---|---|---|---|---|---|
| Rₛᵢ/R_{c} | | 1.10 | 1.00 | 0.70 | 0.60 | 0.47 | 0.40 | 0.30 |
| R_{c} | 1.80 | 0.61 | 0.56 | 0.39 | 0.33 | 0.26 | 0.22 | 0.17 |
| | | E | E | E | E | E | E | E |
| | 1.35 | 0.81 | 0.74 | 0.52 | 0.44 | 0.35 | 0.30 | 0.22 |
| | | E | A | E | E | E | E | E |
| | 1.15 | 0.96 | 0.87 | 0.61 | 0.52 | 0.41 | 0.35 | 0.26 |
| | | C | B | A | E | E | E | E |
| | 0.94 | 1.17 | 1.06 | 0.74 | 0.64 | 0.50 | 0.43 | 0.32 |
| | | C | C | B | C | E | E | E |
| | 0.80 | 1.38 | 1.25 | 0.88 | 0.75 | 0.59 | 0.50 | 0.38 |
| | | C | C | C | D | D | E | E |
| | 0.60 | 1.83 | 1.67 | 1.17 | 1.00 | 0.78 | 0.67 | 0.50 |
| | | C | D | D | D | D | D | E |

Each of the numerical values (1.10, 1.00, 0.70, 0.60, 0.47, 0.40, and 0.30) in the second row from the top in Table 7 indicates a polishing rate (Rₛᵢ) for the Si surface of the silicon carbide single crystal wafer. Each of the numerical values (1.80, 1.35, 1.15, 0.94, 0.80, and 0.60) in the second column from the left in Table 7 indicates a polishing rate (R_{c}) for the C surface of the silicon carbide single crystal wafer. Each of the other numerical values than these numerical values in Table 7 indicate a ratio (Rₛᵢ/R_{c}) of the polishing rate Rₛᵢ for the Si surface of the silicon carbide single crystal wafer and the polishing rate R_{c} for the C surface of the silicon carbide single crystal wafer. Each of symbols A to E in Table 7 represents a result of evaluating the state of the silicon carbide single crystal wafer in accordance with the above-described criteria. It is indicated that excellence in the state of the polished silicon carbide single crystal wafer is increased in the order of E, D, C, B, and A.

In Experiment Example 1, the ratio (Rₛᵢ/R_{c}) of the polishing rate (Rₛᵢ) for the Si surface of the silicon carbide single crystal wafer and the polishing rate (R_{c}) for the C surface of the silicon carbide single crystal wafer was changed to evaluate, in accordance with the above-described criteria, states of silicon carbide single crystal wafers having been through second both-main-surface chemical mechanical polishing step S5. Results are shown in Table 8.

TABLE 8

| | | Rₛᵢ | | | | | | |
|---|---|---|---|---|---|---|---|---|
| Rₛᵢ/R_{c} | | 0.27 | 0.26 | 0.24 | 0.20 | 0.19 | 0.17 | 0.13 |
| R_{c} | 0.62 | 0.44 | 0.42 | 0.39 | 0.32 | 0.31 | 0.27 | 0.21 |
| | | E | E | E | E | E | E | E |
| | 0.49 | 0.55 | 0.53 | 0.49 | 0.41 | 0.39 | 0.35 | 0.27 |
| | | E | A | E | E | E | E | E |
| | 0.46 | 0.59 | 0.57 | 0.52 | 0.43 | 0.41 | 0.37 | 0.28 |
| | | C | B | A | E | E | E | E |
| | 0.40 | 0.68 | 0.65 | 0.60 | 0.50 | 0.48 | 0.43 | 0.33 |
| | | C | C | B | C | E | E | E |
| | 0.32 | 0.84 | 0.81 | 0.75 | 0.63 | 0.59 | 0.53 | 0.41 |
| | | C | C | C | D | D | E | E |
| | 0.25 | 1.08 | 1.04 | 0.96 | 0.80 | 0.76 | 0.68 | 0.52 |
| | | C | D | D | D | D | D | E |

Each of the numerical values (0.27, 0.26, 0.24, 0.20, 0.19, 0.17, and 0.13) in the second row from the top in Table 8 indicates a polishing rate (Rₛᵢ) for the Si surface of the silicon carbide single crystal wafer. Each of the numerical values (0.62, 0.49, 0.46, 0.40, 0.32, and 0.25) in the second column from the left in Table 8 indicates a polishing rate (R_{c}) for the C surface of the silicon carbide single crystal wafer. Each of the other numerical values than these numerical values in Table 8 indicates a ratio (Rₛᵢ/R_{c}) of the polishing rate Rₛᵢ for the Si surface of the silicon carbide single crystal wafer and the polishing rate R_{c} for the C surface of the silicon carbide single crystal wafer. Each of symbols A to E in Table 8 represents a result of evaluating the state of the silicon carbide single crystal wafer in accordance with the above-described criteria.

As shown in Table 7 and Table 8, it is understood that in each of first both-main-surface chemical mechanical polishing step S4 and second both-main-surface chemical mechanical polishing step S5, there is a suitable ratio (Rₛᵢ/R_{c}) of polishing rate Rₛᵢ for the Si surface of the silicon carbide single crystal wafer and polishing rate R_{c} for the C surface of the silicon carbide single crystal wafer to maintain an excellent state of the polished silicon carbide single crystal wafer.

### Experiment Example 6

In Experiment Example 1, the ratio (Aₛᵢ/A_{c}) of effective surface area ratio Aₛᵢ [%] of the polishing cloth for polishing the Si surface of the silicon carbide single crystal wafer and effective surface area ratio A_{c} [%] of the polishing cloth for polishing the C surface of the silicon carbide single crystal wafer was changed to evaluate, in accordance with the above-described criteria A to E, states of silicon carbide single crystal wafers having been through first both-main-surface chemical mechanical polishing step S4.

Further, in Experiment Example 1, the ratio (Aₛᵢ/A_{c}) of effective surface area ratio Aₛᵢ [%] of the polishing cloth for polishing the Si surface of the silicon carbide single crystal wafer and effective surface area ratio A_{c} [%] of the polishing cloth for polishing the C surface of the silicon carbide single crystal wafer was changed to evaluate, in accordance with the above-described criteria A to E, states of silicon carbide single crystal wafers having been through second both-main-surface chemical mechanical polishing step S5.

Evaluation results for the states of these silicon carbide single crystal wafers were the same. The results are shown in Table 9.

TABLE 9

| | | Aₛᵢ[%] | | | | | | |
|---|---|---|---|---|---|---|---|---|
| Aₛᵢ/A_{c} | | 99.7 | 97.7 | 93.2 | 90.0 | 86.9 | 80.8 | 63.8 |
| A_{c} | 98.0 | 1.01 | 0.99 | 0.95 | 0.92 | 0.89 | 0.82 | 0.65 |
| [%] | | E | E | E | E | E | E | E |
| | 93.5 | 1.06 | 1.04 | 0.99 | 0.96 | 0.93 | 0.86 | 0.68 |
| | | C | A | E | E | E | E | E |
| | 90.3 | 1.10 | 1.08 | 1.03 | 0.99 | 0.96 | 0.89 | 0.71 |
| | | C | B | A | E | E | E | E |
| | 87.2 | 1.14 | 1.12 | 1.07 | 1.03 | 0.99 | 0.93 | 0.73 |
| | | C | C | B | C | E | E | E |
| | 81.1 | 1.23 | 1.20 | 1.15 | 1.11 | 1.07 | 0.99 | 0.77 |
| | | C | C | C | D | D | E | E |
| | 64.1 | 1.56 | 1.60 | 1.45 | 1.40 | 1.36 | 1.26 | 0.99 |
| | | D | D | D | D | D | D | E |

Each of the numerical values (99.7, 97.7, 93.2, 90.0, 86.9, 80.8, and 63.8) in the second row from the top in Table 9 indicates an effective surface area ratio Aₛᵢ [%] of the polishing cloth for polishing the Si surface of the silicon carbide single crystal wafer. Each of the numerical values (98.0, 93.5, 90.3, 87.2, 81.1, and 64.1) in the second column from the left in Table 9 indicate an effective surface area ratio A_{c} [%] of the polishing cloth for polishing the C surface of the silicon carbide single crystal wafer. Each of the other numerical values than these numerical values in Table 9 indicates a ratio (Aₛᵢ/A_{c}) of effective surface area ratio Aₛᵢ [%] of the polishing cloth for polishing the Si surface of the silicon carbide single crystal wafer and effective surface area ratio A_{c} [%] of the polishing cloth for polishing the C surface of the silicon carbide single crystal wafer. Each of symbols A to E in Table 9 represents a result of evaluating the state of the silicon carbide single crystal wafer in accordance with the same criteria as in Experiment Example 5.

As shown in Table 9, it is understood that in each of first both-main-surface chemical mechanical polishing step S4 and second both-main-surface chemical mechanical polishing step S5, there is a suitable ratio (Aₛᵢ/A_{c}) of effective surface area ratio Aₛ [%] of the polishing cloth for polishing the Si surface of the silicon carbide single crystal wafer and effective surface area ratio A_{c} [%] of the polishing cloth for polishing the C surface of the silicon carbide single crystal wafer to maintain an excellent state of the polished silicon carbide single crystal wafer.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

10: silicon carbide substrate; 10a, 10b, 10c, 10d: both end portions; 11: first main surface; 12: second main surface; 13: orientation flat; 34: polishing cloth; 34a: effective polishing surface; 34b: groove; 41: first square region; 41a: lowest point; 41b: highest point; 42: second square region; 42a: lowest point; 42b: highest point; 43: third square region; 43a: lowest point; 43b: highest point; 44: fourth square region; 44a: lowest point; 44b: highest point; 45: fifth square region; 45a: center; 45b: highest point; 45c: lowest point; 50: central region; 51a, 51b: first region; 51c, 51d: second region; 101: first radial direction; 101a: first imaginary straight line; 102: second radial direction; 102a: second imaginary straight line; 410a, 410b: region; T1, T2, T3, T4, T5, T6, T7, T8, T9, T10: height; S1, S2, S3, S4, S5: step.

1. A silicon carbide substrate comprising: a first main surface having a circular shape and provided with an orientation flat; and a second main surface opposite to the first main surface, wherein
when a shape of the first main surface before the orientation flat is provided is a circle, the first main surface has a center of the circle,
when it is assumed that a first imaginary straight line is provided to extend in a first radial direction of the first main surface through the center of the circle, the first main surface includes first both-end portions in the first radial direction, the first both-end portions being two intersections between the first imaginary straight line and a peripheral edge of the first main surface in the first radial direction,
when it is assumed that a second imaginary straight line is provided to extend in a second radial direction of the first main surface through the center of the circle, the first main surface includes second both-end portions in the second radial direction, the second both-end portions being two intersections between the second imaginary straight line and the peripheral edge of the first main surface in the second radial direction, the second radial direction being orthogonal to the first radial direction,
the first main surface includes a central region other than a first region and a second region, the first region being a region extending by less than or equal to 5 mm from each of the first both-end portions in the first radial direction toward an inner side of the first main surface, the second region being a region extending by less than or equal to 5 mm from each of the second both-end portions in the second radial direction toward the inner side of the first main surface, and
an average value of LTVs of a plurality of first square regions of a plurality of square regions is less than or equal to 0.75 μm, the plurality of first square regions being disposed in a form of a ring on an outermost side with respect to the center of the circle so as to form an outermost periphery when the central region of the first main surface is divided into the plurality of square regions to provide a largest number of square regions, each of the square regions exactly forming a square having each side of 5 mm.

2. The silicon carbide substrate according to claim 1, wherein the average value of the LTVs of the plurality of first square regions is more than or equal to 0.1 μm.

3. The silicon carbide substrate according to claim 1, wherein an average value of LTVs of a plurality of second square regions of the plurality of square regions is less than or equal to 0.4 μm, the plurality of second square regions being disposed adjacent to the plurality of first square regions on an inner side in the first radial direction or the second radial direction with respect to the plurality of first square regions, the plurality of second square regions being disposed in a form of a ring so as to form an inner periphery of the ring formed by the plurality of first square regions.

4. The silicon carbide substrate according to claim 3, wherein the average value of the LTVs of the plurality of second square regions is more than or equal to 0.1 μm.

5. The silicon carbide substrate according to claim 3, wherein an average value of LTVs of a plurality of third square regions of the plurality of square regions is less than or equal to 0.3 μm, the plurality of third square regions being disposed adjacent to the plurality of second square regions on an inner side in the first radial direction or the second radial direction with respect to the plurality of second square regions, the plurality of third square regions being disposed in a form of a ring so as to form an inner periphery of the ring formed by the plurality of second square regions.

6. The silicon carbide substrate according to claim 5, wherein the average value of the LTVs of the plurality of third square regions is more than or equal to 0.1 μm.

7. The silicon carbide substrate according to claim 5, wherein an average value of LTVs of a plurality of fourth square regions of the plurality of square regions is less than or equal to 0.25 μm, the plurality of fourth square regions being disposed adjacent to the plurality of third square regions on an inner side in the first radial direction or the second radial direction with respect to the plurality of third square regions, the plurality of fourth square regions being disposed in a form of a ring so as to form an inner periphery of the ring formed by the plurality of third square regions.

8. The silicon carbide substrate according to claim 7, wherein the average value of the LTVs of the plurality of fourth square regions is more than or equal to 0.1 μm.

9. A method of manufacturing a silicon carbide substrate, the method comprising:
forming a silicon carbide single crystal wafer by slicing an ingot composed of a silicon carbide single crystal;
chamfering the silicon carbide single crystal wafer by cutting a corner of the silicon carbide single crystal wafer;
roughly polishing both main surfaces of the chamfered silicon carbide single crystal wafer;
performing first both-main-surface chemical mechanical polishing at least once onto the roughly polished silicon carbide single crystal wafer using a polishing cloth and a polishing liquid; and
performing second both-main-surface chemical mechanical polishing at least once onto the silicon carbide single crystal wafer having been through the first both-main-surface chemical mechanical polishing, using a polishing cloth and a polishing liquid different from the polishing cloth and the polishing liquid used in the performing of the first both-main-surface chemical mechanical polishing, wherein
in at least one of the performing of the first both-main-surface chemical mechanical polishing and the performing of the second both-main-surface chemical mechanical polishing, Aₛᵢ and A_{c} satisfy the following formulas (6) to (8):
Aₛᵢ≥80 and A_{c}≥80 (6),
Aₛᵢ≥90 and A_{c}<90 (7), and
1<(Aₛᵢ/A_{c})<1.25 (8), where
Aₛᵢ represents an effective surface area ratio of the polishing cloth for polishing a Si surface of the silicon carbide single crystal wafer, and A_{c} represents an effective surface area ratio of the polishing cloth for polishing a C surface of the silicon carbide single crystal wafer, and
in at least one of the performing of the first both-main-surface chemical mechanical polishing and the performing of the second both-main-surface chemical mechanical polishing, a ratio (Rₛᵢ/R_{c}) of a polishing rate Rₛᵢ for the Si surface of the silicon carbide single crystal wafer and a polishing rate R_{c} for the C surface of the silicon carbide single crystal wafer is more than or equal to 0.6 and less than or equal to 1.4.
